(19) United States
(12) Patent Application Publication
(10) Pub. No.: US 2012/0299599 A1
(43) Pub. Date: Nov. 29, 2012

(54) ELECTRIC LEAKAGE SENSING APPARATUS

(75) Inventors: Hideaki Naruse, Iida-shi (JP); Satoru Miyamoto, Owariasahi-shi (JP); Masaki Fujii, Iida-shi (JP); Kazushi Kodaira, Kasugai-shi (JP); Yoshihiro Ikushima, Kasugai-shi (JP)

(73) Assignee: OMRON AUTOMOTIVE ELECTRONICS CO., LTD., Komaki (JP)

(21) Appl. No.: 13/477,878

(22) Filed: May 22, 2012

(30) Foreign Application Priority Data
May 23, 2011 (JP) 2011-114977

(51) Int. Cl. G01R 31/40

(52) U.S. Cl. 324/509

(57) ABSTRACT

An electric leakage sensing apparatus includes a pulse generator that supplies a pulse to a coupling capacitor, a voltage detector that detects a voltage at the coupling capacitor, an electric leakage determination unit that compares the voltage detected by the voltage detector to a threshold and determines existence or non-existence of an electric leakage of a DC power supply based on a comparison result, a pre-check circuit that puts the DC power supply into a pseudo electric leakage state, a diagnostic unit that diagnoses whether the electric leakage determination unit determines that the electric leakage exists when the DC power supply is put into the pseudo electric leakage state, and terminals to which cables are connected. A current route from the pulse generator to the pre-check circuit through the coupling capacitor and the cables is formed when the DC power supply is put into the pseudo electric leakage state.

### TECHNICAL FIELD

The present invention relates to an electric leakage sensing apparatus that is used to sense an electric leakage of a DC power supply in, for example, an electric automobile.

### RELATED ART

A high-voltage DC power supply is mounted on the electric automobile in order to drive a motor and an in-vehicle instrument. The DC power supply is electrically insulated from a grounded vehicle body. However, when an insulation failure or a short circuit is generated between the DC power supply and the vehicle body for any cause, a current is passed through a route from the DC power supply to the ground to generate an electric leakage. Therefore, an electric leakage sensing apparatus that senses the electric leakage is provided in the DC power supply.

Some electric leakage sensing apparatuses include what is called a self-diagnostic function of being able to check whether the electric leakage is normally sensed, and some electric leakage sensing apparatuses include a disconnection detecting function of being able to detect disconnection. Japanese Unexamined Patent Publication Nos. 2005-127821 and 2007-163291 disclose an electric leakage sensing apparatus including the self-diagnostic function. Japanese Unexamined Patent Publication No. 2004-361309 discloses an electric leakage sensing apparatus including the disconnection detecting function.

In the electric leakage detection apparatus disclosed in Japanese Unexamined Patent Publication No. 2005-127821, a resistor and a switch element, which are used for self-diagnosis, are connected in series between a ground and a connection point of a detection resistor and an insulation resistor, and determination means for determining whether the detection resistor is degraded or broken down is provided. During a self-diagnostic operation, the determination means determines that the detection resistor is degraded or broken down, when a voltage emerging at the connection point of the detection resistor and the insulation resistor differs from a reference value with the switch element turned on.

In the insulating performance diagnostic apparatus disclosed in Japanese Unexamined Patent Publication No. 2007-163291, which applies a pulse voltage to an insulation-to-the-earth circuit through a coupling capacitor to determine the insulation of the insulation-to-the-earth circuit according to a signal voltage substantially proportional to an electric leakage current passed through the insulation-to-the-earth circuit, a pseudo insulation decreasing circuit is provided to generate the same signal change as with the decrease of the insulation-to-the-earth resistor of the insulation-to-the-earth circuit.

The motor driving apparatus disclosed in Japanese Unexamined Patent Publication No. 2004-361309, which detects an insulation failure based on a frequency component of a leakage current to the earth, includes a waveform forming circuit that outputs a pulse based on a comparison result of an output of a leakage current detection circuit and a threshold and a disconnection determination circuit that determines that the disconnection is generated in a route from a power supply to an insulation failure detection circuit when the waveform forming circuit does not output the pulse having a predetermined frequency.

FIG. 4 illustrates an example of an electric leakage sensing apparatus of the related art including a self-diagnostic function. An electric leakage sensing apparatus 200 includes a CPU 1, a pulse generator 2, a filter circuit 3, a pre-check circuit 4, a memory 5, a resistor R1, and coupling capacitors C1 and C3. The CPU 1 includes a voltage detector 6, an electric leakage determination unit 7, and a diagnostic unit 8. The filter circuit 3 includes a resistor R2 and a capacitor C2. The pre-check circuit 4 includes a transistor Q and resistors R3 to R5. A negative-electrode side of a DC power supply 300 (high-voltage battery) is connected to the coupling capacitors C1 and C3 of the electric leakage sensing apparatus 200 through a cable W. A positive-electrode side of the DC power supply 300 is connected to a load, such as a motor and an in-vehicle instrument.

An operation of the electric leakage sensing apparatus 200 at a normal time will be described below. A pulse (FIG. 6A) output from the pulse generator 2 charges the coupling capacitor C1 through the resistor R1, and a potential at a point P rises by the charging. The potential at the point P is input as an input voltage V to the CPU 1 through the filter circuit 3. The voltage detector 6 of the CPU 1 detects the voltage at the coupling capacitor C1 based on the input voltage V. Hereinafter the detected voltage at the coupling capacitor C1 is referred to as a “detection voltage”.

When the electric leakage is not generated in the DC power supply 300, the detection voltage rises steeply as illustrated by a solid line in FIG. 5. Therefore, the detection voltage exceeds a threshold SH during a time interval until the pulse falls at a time t1 since the pulse rises at a time t0. On the other hand, when the electric leakage is generated in the DC power supply 300, the detection voltage rises moderately due to an electric leakage impedance as illustrated by a broken line in FIG. 5. Therefore, the detection voltage does not exceed the threshold SH during the time interval from the time t0 to the time t1.

The voltage detector 6 detects the voltage at the coupling capacitor C1 at the time t1 the pulse falls. The detection voltage becomes Va when the electric leakage is not generated, and the detection voltage becomes Vb when the electric leakage is generated. The electric leakage determination unit 7 of the CPU 1 compares the detection voltage and the threshold SH. The electric leakage determination unit 7 determines that “the electric leakage does not exist” when the detection voltage is not lower than the threshold SH (Va), and the electric leakage determination unit 7 determines that “the electric leakage exists” when the detection voltage is lower than the threshold SH (Vb). When “the electric leakage exists,” the CPU 1 outputs an electric leakage sensing signal.

An operation of the electric leakage sensing apparatus 200 during a self-diagnosis will be described below. When the self-diagnosis is performed, a pre-check request signal is input to the CPU 1 as illustrated in FIG. 6. In response to the pre-check request signal, the diagnostic unit 8 of the CPU 1 turns on a transistor Q of the pre-check circuit 4 in order to form a pseudo electric leakage state. Therefore, a current route Y from the pulse generator 2 to the pre-check circuit 4 through the resistor R1 and the coupling capacitors C1 and C3 is formed as indicated by a broken-line arrow in FIG. 4. Therefore, the coupling capacitors C1 and C3 are charged by the pulse output from the pulse generator 2. As a result, the potential at the point P, namely, the input voltage V rises moderately. As illustrated in FIG. 6C, the electric leakage determination unit 7 determines that “the electric leakage exists” because the detection voltage at the coupling capacitor C1 becomes lower than the threshold SH. As illustrated in FIG. 6D, the CPU 1 outputs the electric leakage sensing signal based on the determination. Therefore, the diagnostic unit 8 determines that the electric leakage is normally sensed.

However, in the electric leakage sensing apparatus 200 of the related art, the current route Y in FIG. 4 is formed in the electric leakage sensing apparatus 200. Therefore, even if the cable W is disconnected, the current route Y is formed during the self-diagnosis, and the operation in FIG. 6 is performed to output the electric leakage sensing signal. That is, irrespective of the disconnection of the cable W, the determination that the electric leakage sensing operation is normally performed is made in the self-diagnosis.

However, when the cable W is disconnected, the original electric leakage cannot be detected because the electric leakage sensing apparatus 200 is separated from the DC power supply 300. Accordingly, when the normal electric leakage sensing operation is made in the self-diagnosis irrespective of the abnormal state, the electric leakage sensing apparatus 200 continues the operation while the electric leakage cannot be detected.

The present invention has been devised to solve the problems described above, and an object thereof is to be able to sense an abnormality caused by the disconnection when the cable connecting the electric leakage sensing apparatus and the DC power supply is disconnected.

### SUMMARY

In accordance with one aspect of the present invention, an electric leakage sensing apparatus includes: a coupling capacitor whose one end is connected to a DC power supply; a pulse generator that supplies a pulse to the other end of the coupling capacitor; a voltage detector that detects a voltage at the coupling capacitor charged with the pulse; an electric leakage determination unit that compares the voltage detected by the voltage detector to a threshold and determines existence or non-existence of an electric leakage of the DC power supply based on a comparison result; a pseudo electric leakage circuit that puts the DC power supply into a pseudo electric leakage state; a diagnostic unit that diagnoses whether the electric leakage determination unit determines that the electric leakage exists when the pseudo electric leakage circuit puts the DC power supply into the pseudo electric leakage state; a first terminal that connects the other end of a first cable whose one end is connected to the DC power supply to one end of the coupling capacitor; and a second terminal that connects the other end of a second cable whose one end is connected to the DC power supply to the pseudo electric leakage circuit. A current route from the pulse generator to the pseudo electric leakage circuit through the coupling capacitor, the first terminal, the first cable, the second cable, and the second terminal is formed when the pseudo electric leakage circuit puts the DC power supply into the pseudo electric leakage state.

Because the current route from the pulse generator to the pseudo electric leakage circuit passes through the first cable and the second cable, the current route is not formed when one of or both the first and second cables are disconnected. Therefore, the voltage at the coupling capacitor, which is detected by the voltage detector, exerts a different change from the voltage in the pseudo electric leakage state because the pseudo electric leakage circuit cannot form the pseudo electric leakage state during the self-diagnosis. Accordingly, the abnormality caused by the disconnection of the cable between the power supply and the electric leakage sensing apparatus can be sensed based on the voltage state of the coupling capacitor.

In the aspect of the invention, a second coupling capacitor may be provided between the second terminal and the pseudo electric leakage circuit.

In the aspect of the invention, the electric leakage sensing apparatus further includes a disconnection sensing unit that senses that one of or both the first cable and the second cable are disconnected, wherein the disconnection sensing unit may sense the disconnection based on the fact that the voltage at the coupling capacitor, which is detected by the voltage detector, becomes the threshold or more while a driving signal is provided to the pseudo electric leakage circuit.

In the aspect of the invention, the disconnection sensing unit may sense the disconnection, when the voltage at the coupling capacitor is continuously equal to or more than for a certain period of time after the driving signal is provided to the pseudo electric leakage circuit.

According to the invention, when the cable connecting the electric leakage sensing apparatus and the DC power supply is disconnected, the abnormality caused by the cable disconnection can be sensed because the pseudo electric leakage state is not formed during the self-diagnosis.

### BRIEF DESCRIPTION OF THE DRAWINGS

FIG. 1 is a circuit diagram illustrating an electric leakage sensing apparatus according to an embodiment of the invention;

FIGS. 2A to 2D are a timing chart illustrating an operation during non-disconnection;

FIGS. 3A to 3E are a timing chart illustrating an operation during disconnection;

FIG. 4 is a circuit diagram illustrating an electric leakage sensing apparatus of the related art;

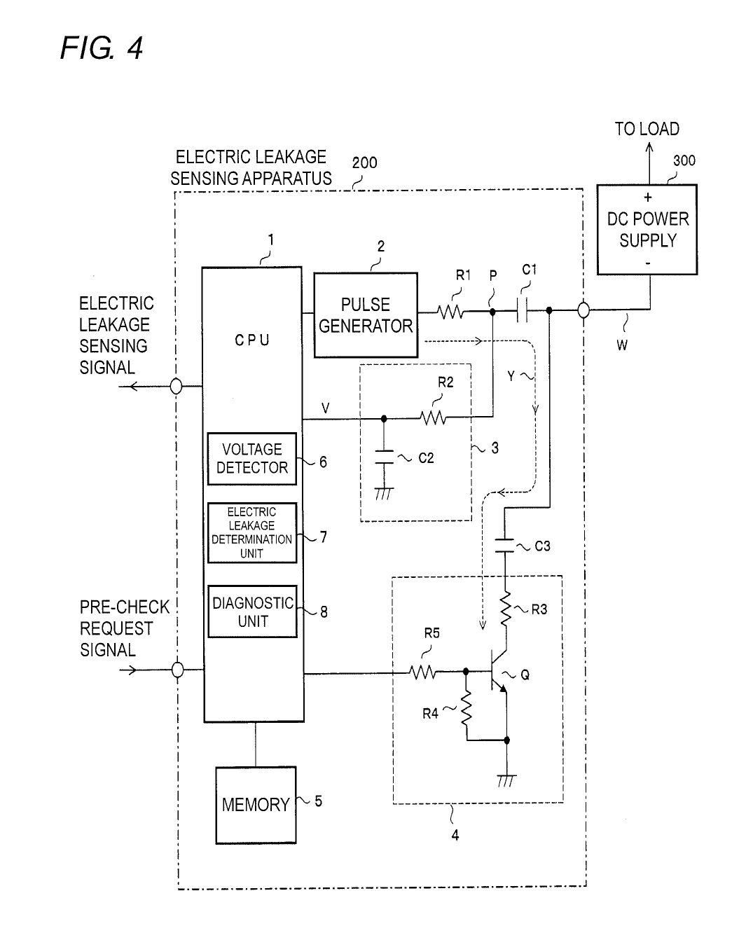

FIG. 5 is a waveform chart of a detection voltage during an electric leakage and a non-electric leakage; and

FIGS. 6A to 6D are a timing chart illustrating an operation of the electric leakage sensing apparatus of the related art.

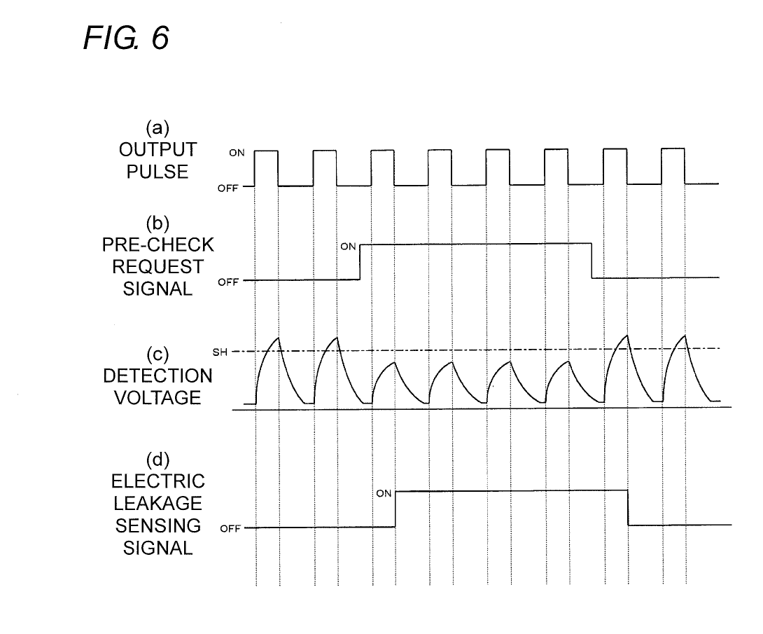

### DETAILED DESCRIPTION

Hereinafter, a preferred embodiment of the present invention will be described with reference to the drawings. In the following drawings, the identical or equivalent component is designated by the identical numeral. The case that the invention is applied to an electric leakage sensing apparatus mounted on an electric automobile will be described below by way of example.

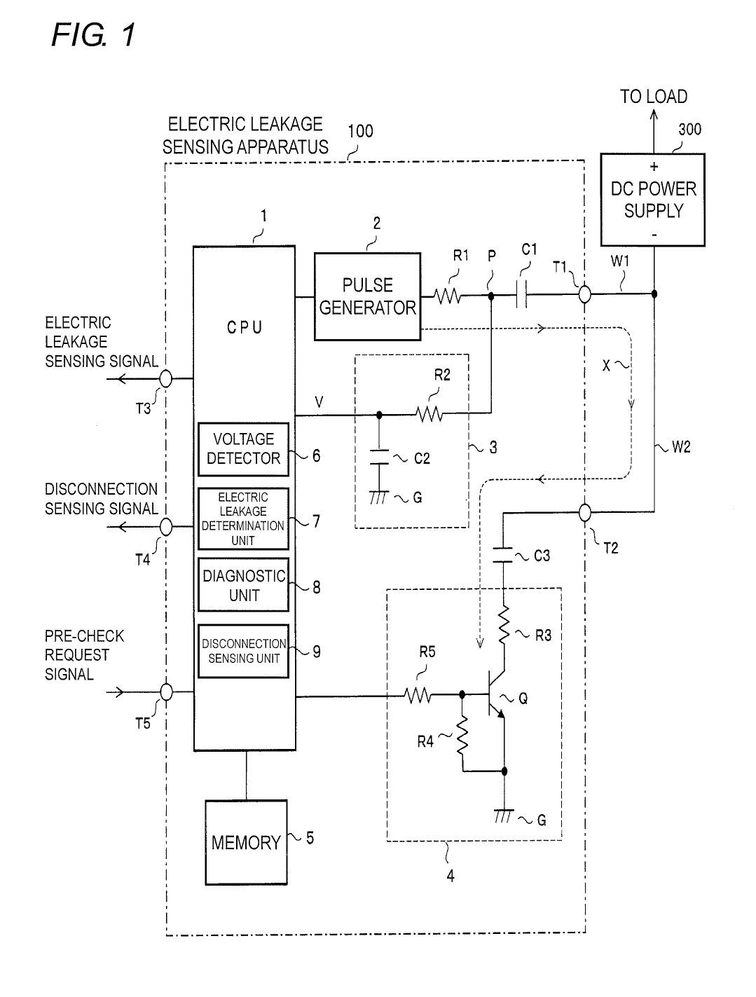

Referring to FIG. 1, a negative-electrode side of an in-car DC power supply 300 (high-voltage battery) and an electric leakage sensing apparatus 100 are connected through cables W1 and W2. A positive-electrode side of the DC power supply 300 is connected to a load, such as a motor and an in-vehicle instrument. The electric leakage sensing apparatus 100 includes a CPU 1, a pulse generator 2, a filter circuit 3, a pre-check circuit 4, a memory 5, a resistor R1, coupling capacitors C1 and C3, and terminals T1 to T5.

The CPU 1 constitutes a controller that controls an operation of the electric leakage sensing apparatus 100. The CPU 1 includes a voltage detector 6, an electric leakage determination unit 7, a diagnostic unit 8, and a disconnection sensing unit 9. Actually functions of the blocks 6 to 9 are implemented by software. The pulse generator 2 generates a pulse having a predetermined frequency based on a command from the CPU 1. The resistor R1 is connected onto an output side of the pulse generator 2. The coupling capacitor C1 separates the DC power supply 300 and the electric leakage sensing apparatus 100 in a DC manner, and is connected between the resistor R1 and the terminal T1 (first terminal).

The filter circuit 3 is provided between the CPU 1 and a connection point (point P) of the resistor R1 and the coupling capacitor C1. The filter circuit 3 removes a noise of a voltage input to the CPU 1, and includes a resistor R2 and a capacitor C2. One end of the resistor R2 is connected to the point P. The other end of the resistor R2 is connected to both the CPU 1 and one end of the capacitor C2. The other end of the capacitor C2 is connected to a ground G. In the embodiment, the ground G is a vehicle body of an electric automobile.

The coupling capacitor C3 is connected between the pre-check circuit 4 and the terminal T2 (second terminal). Similarly to the coupling capacitor C1, the coupling capacitor C3 separates the DC power supply 300 and the electric leakage sensing apparatus 100 in the DC manner. The coupling capacitor C3 corresponds to the second coupling capacitor of the invention.

The pre-check circuit 4 constitutes the pseudo electric leakage circuit of the invention, and includes a transistor Q and resistors R3 to R5. The resistor R3 is connected to a collector of the transistor Q, and the coupling capacitor C3 is connected to the resistor R3 in series. An emitter of the transistor Q is connected to the ground G. A base of the transistor Q is connected to the CPU 1 through the resistor R5. The resistor R4 is connected to both the base and the emitter of the transistor Q.

The memory 5 includes a ROM and a RAM to constitute a storage unit. An operating program and control data are stored in the memory 5, and a threshold SH used to determine existence or non-existence of the electric leakage is also stored in the memory 5.

The voltage detector 6 of the CPU 1 detects the voltage at coupling capacitor C1 based on an input voltage V input from the point P to the CPU 1 through the filter circuit 3.

The electric leakage determination unit 7 compares the voltage detected by the voltage detector 6 to the threshold SH, and determines the existence or non-existence of the electric leakage of the DC power supply 300 based on the comparison result.

During the self-diagnosis, the diagnostic unit 8 drives the pre-check circuit 4 to puts the DC power supply 300 into a pseudo electric leakage state, and diagnoses whether the electric leakage determination unit 7 determines that “the electric leakage exists” in the pseudo electric leakage state.

The disconnection sensing unit 9 senses that one of or both the cables W1 and W2 are disconnected based on the state of the voltage detected by the voltage detector 6.

One end of the cable W1 (first cable) is connected to the negative electrode of the DC power supply 300. The other end of the cable W1 is connected to the terminal T1 of the electric leakage sensing apparatus 100, and the other end of the cable W1 is connected to one end of the coupling capacitor C1 through the terminal T1.

One end of the cable W2 (second cable) is connected to the negative electrode of the DC power supply 300. The other end of the cable W2 is connected to the terminal T2 of the electric leakage sensing apparatus 100, and the other end of the cable W2 is connected to the one end of the coupling capacitor C3 through the terminal T2.

Actually, for example, one end of the cable W1 is connected to one of the two equal-potential terminals (not illustrated) constituting the negative electrode of the DC power supply 300, and one end of the cable W2 is connected to the other terminal.

The terminals T3 to T5 of the electric leakage sensing apparatus 100 are connected to the CPU 1. An electric leakage sensing signal is output from the terminal T3 when the electric leakage is sensed. A disconnection sensing signal is output from the terminal T4 when the disconnection is sensed. A pre-check request signal is input to the terminal T5 when the self-diagnosis is performed. For example, a superior apparatus (not illustrated) provides the pre-check request signal after a certain period of time elapses since an ignition switch is turned on.

An operation of the electric leakage sensing apparatus 100 having the above configuration will be described below. The operation is described while divided into the case that the cable is not disconnected and the case that the cable is disconnected.

### (1) Operation During Non-Disconnection of Cable

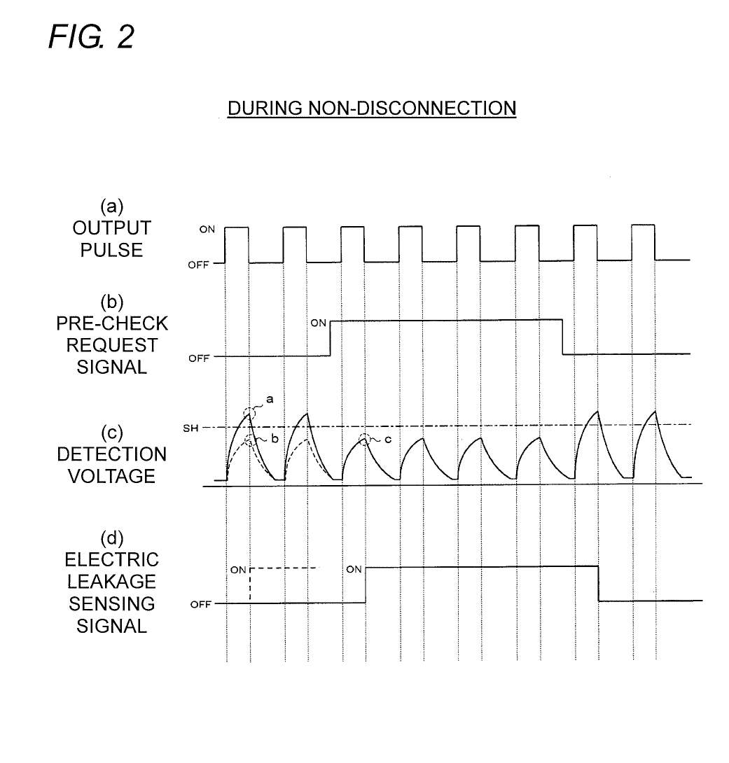

The operation in the case that the cables W1 and W2 are not disconnected will be described with reference to FIG. 2. The pulse generator 2 outputs a rectangular-wave pulse with a predetermined period as illustrated in FIG. 2A. The pulse is supplied to the coupling capacitor C1 through the resistor R1 to charge the coupling capacitor C1. Actually, a floating capacitance exists between the terminals T1 and T2 and the vehicle body, and the floating capacitance is also charged by the pulse. The potential at the point P rises by charging the coupling capacitor C1. The potential at the point P is input as the input voltage V to the CPU 1 through the filter circuit 3.

### <For Non-Existence of Pre-Check Request Signal>

The CPU 1 does not output a driving signal to the pre-check circuit 4 when the pre-check request signal in FIG. 2B is not input to the terminal T5. Therefore, the transistor Q of the pre-check circuit 4 is turned off. At this point, because the current route X indicated by the broken-line arrow in FIG. 1 is not formed, only the coupling capacitor C1 is charged by the pulse output from the pulse generator 2, while the coupling capacitor C3 is not charged.

The voltage detector 6 of the CPU 1 detects the voltage at the coupling capacitor C1 based on the input voltage V. The voltage is detected at the time the pulse supplied to the coupling capacitor C1 falls. Hereinafter the detected voltage at the coupling capacitor C1 is referred to as a “detection voltage”.

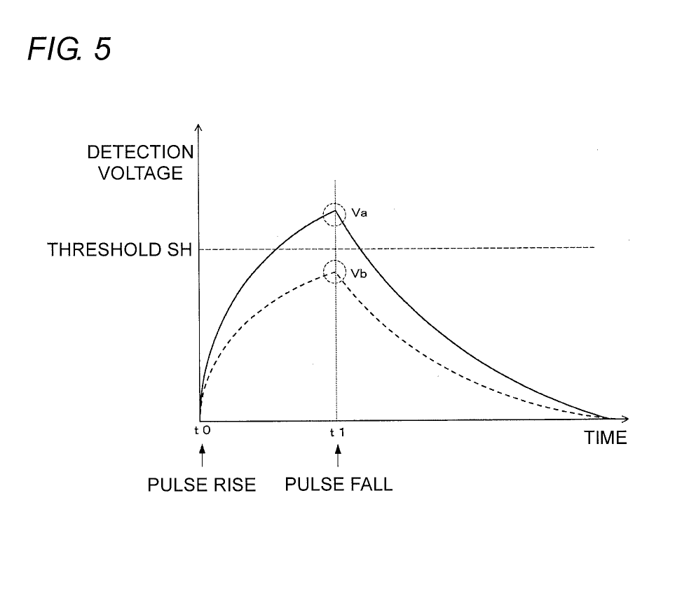

As illustrated in FIG. 5, the electric leakage determination unit 7 compares the voltage detected by the voltage detector 6 to the threshold SH stored in the memory 5, and determines the existence or non-existence of the electric leakage based on the comparison result. Unless the electric leakage is generated in the DC power supply 300, the detection voltage exceeds the threshold SH (a in FIG. 2C). Accordingly, because the electric leakage determination unit 7 determines that “the electric leakage does not exist,” the CPU 1 does not output the electric leakage sensing signal (FIG. 2D). On the other hand, when the electric leakage is generated in the DC power supply 300, because the detection voltage does not exceed the threshold SH (b in FIG. 2C), the electric leakage determination unit 7 determines that “the electric leakage exists.” In this case, the CPU 1 outputs the electric leakage sensing signal (a broken line in FIG. 2).

### <For Existence of Pre-Check Request Signal>

During the self-diagnosis, the superior apparatus inputs the pre-check request signal in FIG. 2B to the terminal T5. Therefore, the CPU 1 outputs the driving signal to the pre-check circuit 4 at the same time. The driving signal is an H (High) level signal used to turn on the transistor Q. The driving signal is provided to the base through the resistor R5, thereby turning on the transistor Q.

When the transistor Q is turned on, the current route X of “pulse generator 2→resistor R1→coupling capacitor C1→terminal T1→cable W1→cable W2→terminal T2→coupling capacitor C3→pre-check circuit 4” is formed as indicated by the broken-line arrow in FIG. 1. Because the emitter of the transistor Q of the pre-check circuit 4 is connected to the ground G (vehicle body), the same pseudo electric leakage state as with the actual generation of the electric leakage between DC power supply 300 and the vehicle body is formed by tuning on the transistor Q.

In the pseudo electric leakage state, both the coupling capacitor C1 and the coupling capacitor C3 are charged by the pulse output from the pulse generator 2. Therefore, the increase in the potential at the point P, namely, the input voltage V becomes moderate. As a result, because the detection voltage at the coupling capacitor C1 becomes lower than the threshold SH (c in FIG. 2C), the electric leakage determination unit 7 determines that “the electric leakage exists.” Based on the determination result, the CPU 1 outputs the electric leakage sensing signal as indicated by a solid line in FIG. 2D. Therefore, the diagnostic unit 8 determines that the electric leakage is normally sensed.

Then the input of the pre-check request signal to the terminal T5 is stopped in order to end the self-diagnosis. At the same time, the output of the driving signal is stopped, and the transistor Q of the pre-check circuit 4 is turned off again. Therefore, the current route X is not formed, the pseudo electric leakage state is released, and the electric leakage sensing apparatus 100 returns to the pre-self-diagnosis state.

### (2) Operation During Cable Disconnection

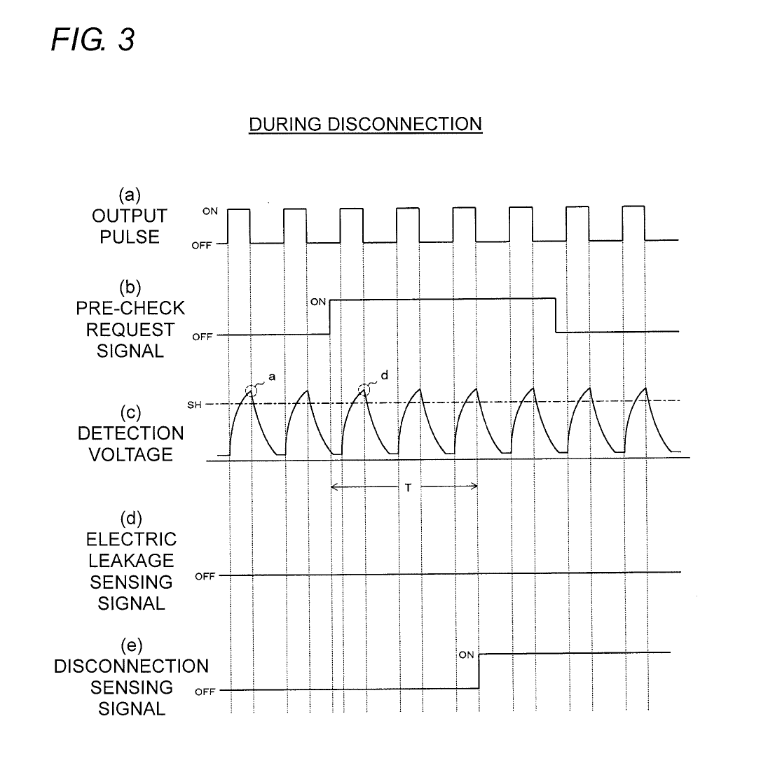

The operation in the case that the cables W1 and W2 are disconnected will be described with reference to FIG. 3. When the cable W2 is disconnected, the electric leakage can be sensed through the cable W1. However, the self-diagnosis cannot be performed because the current route X is not formed. When the cable W1 is disconnected, the electric leakage cannot be sensed because the point P in FIG. 1 is separated from the DC power supply 300, and the self-diagnosis cannot be performed because the current route X is not formed. The case that the cable W1 is disconnected will be described by way of example.

### <For Non-Existence of Pre-Check Request Signal>

As described above, the charging route from the pulse generator 2 to the coupling capacitor C1 is maintained, because the floating capacitance exists between the terminal T1 and the vehicle body (ground) even if the cable W1 is disconnected. However, the coupling capacitor C3 is not charged due to the disconnection of the cable W1. Therefore, the detection voltage detected by the voltage detector 6 exceeds the threshold SH (a in FIG. 3C). Accordingly, the electric leakage determination unit 7 determines that “the electric leakage does not exist,” and the CPU 1 does not output the electric leakage sensing signal (FIG. 3D).

### <For Existence of Pre-Check Request Signal>

As described above, when the pre-check request signal is input to the terminal T5 during the self-diagnosis (FIG. 3B), the CPU 1 outputs the driving signal to the pre-check circuit 4 in order to turn on the transistor Q. However, when the cable W1 is disconnected, the current route X in FIG. 1 is not formed irrespective of the state of the transistor Q. Only the coupling capacitor C1 is charged by the pulse of the pulse generator 2, but the current is not passed to the ground G from the coupling capacitor C3 through the resistor R3 and the transistor Q of the pre-check circuit 4. That is, the pre-check circuit 4 cannot form the pseudo electric leakage state. The same holds true for not only the case that the cable W2 is disconnected but also the case that both the cables W1 and W2 are disconnected.

Accordingly, unlike c in FIG. 2C, the voltage at the coupling capacitor C1, namely, the detection voltage exceeds threshold SH as indicated by d in FIG. 3C. Therefore, because the electric leakage determination unit 7 determines that “the electric leakage does not exist,” the electric leakage sensing signal is not output as illustrated in FIG. 3D.

In this case, based on the fact that the detection voltage becomes threshold SH or more, the disconnection sensing unit 9 senses the disconnection while the driving signal is provided to the pre-check circuit 4. More particularly, the disconnection sensing unit 9 senses that one of or both the cables W1 and W2 are disconnected, when the detection voltage detected by the voltage detector 6 is continuously equal to or more than the threshold SH for a certain period of time (T in FIG. 3) after the driving signal is output to the pre-check circuit 4 in response to the pre-check request signal. When the disconnection sensing unit 9 senses the cable disconnection, the CPU 1 outputs the disconnection sensing signal as illustrated in FIG. 3E. The disconnection sensing signal is transmitted to the superior apparatus through the terminal T4, and the superior apparatus processes the abnormal state (for example, an output of an alarm indicating the disconnection).

In the embodiment, the cable connecting the electric leakage sensing apparatus 100 and the DC power supply 300 is divided into two, the terminal T1 and the DC power supply 300 are connected through the cable W1 while the terminal T2 and the DC power supply 300 are connected through the cable W2. During the self-diagnosis, the current route X for the pseudo electric leakage is formed from the pulse generator 2 to the pre-check circuit 4 through the resistor R2, the coupling capacitor C1, the terminal T1, the cable W1, the cable W2, the terminal T2, and the coupling capacitor C3.

Because the current route X always passes through the cables W1 and W2, neither the current route X nor the pseudo electric leakage state are formed when one of or both the cables W1 and W2 are disconnected. Therefore, the voltage at the coupling capacitor C1 exerts the different change from the voltage in the pseudo electric leakage state, and the detection voltage detected by the voltage detector 6 becomes the threshold SH or more. Based on this, the abnormality caused by the disconnection can be sensed during the self-diagnosis. As a result, the failure that the electric leakage sensing apparatus 100 is continuously operated while the electric leakage cannot be sensed can be prevented from occurring.

In addition to the above embodiment, various modifications can be made in the invention. For example, by way of example, the filter circuit 3 including the resistor R2 and the capacitor C2 is provided in the embodiment. However, it is not always necessary to provide the filter circuit 3, but the filter circuit 3 may be eliminated. As needed basis, a discharge circuit may be added in order to forcedly discharge the charges charged in the coupling capacitors C1 and C3.

In the embodiment, while the voltage detector 6 detects the voltage at the coupling capacitor C1 at the time pulse output from the pulse generator 2 falls, the electric leakage determination unit 7 determines the existence or non-existence of the electric leakage. However, the invention is not limited to the embodiment. For example, at a predetermined time before the pulse falls, the voltage detector 6 may perform the voltage detection, and the electric leakage determination unit 7 may determine the existence or non-existence of the electric leakage.

In the embodiment, by way of example, the pre-check circuit 4 includes the transistor Q and the resistors R4 and R5. Alternatively, the pre-check circuit 4 may include a coil and a relay having a contact instead of the transistor Q and the resistors R4 and R5.

In the embodiment, by way of example, the invention is applied to the electric leakage sensing apparatus mounted on the electric automobile. Alternatively, the invention may be applied to an electric leakage sensing apparatus that is used in applications except the electric automobile.

What is claimed is:

1. An electric leakage sensing apparatus comprising:
a coupling capacitor whose one end is connected to a DC power supply;
a pulse generator that supplies a pulse to the other end of the coupling capacitor;
a voltage detector that detects a voltage at the coupling capacitor charged with the pulse;
an electric leakage determination unit that compares the voltage detected by the voltage detector to a threshold and determines existence or non-existence of an electric leakage of the DC power supply based on a comparison result;
a pseudo electric leakage circuit that puts the DC power supply into a pseudo electric leakage state;
a diagnostic unit that diagnoses whether the electric leakage determination unit determines that the electric leakage exists when the pseudo electric leakage circuit puts the DC power supply into the pseudo electric leakage state;
a first terminal that connects the other end of a first cable whose one end is connected to the DC power supply to one end of the coupling capacitor; and a second terminal that connects the other end of a second cable whose one end is connected to the DC power supply to the pseudo electric leakage circuit, wherein
a current route from the pulse generator to the pseudo electric leakage circuit through the coupling capacitor, the first terminal, the first cable, the second cable, and the second terminal is formed when the pseudo electric leakage circuit puts the DC power supply into the pseudo electric leakage state.

2. The electric leakage sensing apparatus according to claim 1, wherein a second coupling capacitor is provided between the second terminal and the pseudo electric leakage circuit.

3. The electric leakage sensing apparatus according to claim 1, further comprising
a disconnection sensing unit that senses that one of or both the first cable and the second cable are disconnected, wherein
the disconnection sensing unit senses the disconnection based on the fact that the voltage at the coupling capacitor, which is detected by the voltage detector, becomes the threshold or more while a driving signal is provided to the pseudo electric leakage circuit.

4. The electric leakage sensing apparatus according to claim 3, wherein the disconnection sensing unit senses the disconnection, when the voltage at the coupling capacitor is continuously equal to or more than for a certain period of time after the driving signal is provided to the pseudo electric leakage circuit.
